(19) United States
(12) Patent Application Publication
(10) Pub. No.: US 2010/0167204 A1
(43) Pub. Date: Jul. 1, 2010

(54) RADIATION-SENSITIVE INSULATION RESIN COMPOSITION, CURED ARTICLE, AND ELECTRONIC DEVICE

(75) Inventors: Ryuichi Okuda, Tokyo (JP); Hirofumi Goto, Tokyo (JP)

Correspondence Address: DITTHAVONG MORI & STEINER, P.C., 918 Prince Street, Alexandria, VA, 22314, US

(73) Assignee: JSR CORPORATION, Tokyo (JP)

(21) Appl. No.: 12/377,721

(22) PCT Filed: Jul. 19, 2007
(86) PCT No.: PCT/JP2007/064224

§ 371 Date: Feb. 17, 2009

(51) Int. Cl. G03F 7/004

(52) U.S. Cl. 430/280.1; 430/270.1

(57) ABSTRACT

A radiation-sensitive insulation resin composition contains (A) an alkali-soluble resin, (B) a crosslinking agent, (C) a radiation-sensitive acid generator, (D) an inorganic filler, and (E) crosslinked rubber particles. The composition can be developed using an alkali developer, does not incur damages in insulating properties and resolution properties, suppresses thermal deformation, and can produce a layer exhibiting excellent adhesion to conductor wiring layers.

### TECHNICAL FIELD

The present invention relates to a radiation-sensitive insulation resin composition, a cured article formed from the radiation-sensitive insulation resin composition, and an electronic device. More particularly, the present invention relates to a radiation-sensitive insulation resin composition suitably used as a material for forming an insulating layer which is interposed between two laminated conductive wiring layers, a cured article formed from the radiation-sensitive insulation resin composition, and an electronic device.

### BACKGROUND ART

Along with an increase in the density of semiconductor devices of electronic equipment, multilayered wiring boards in which two or more conductor wiring layers are laminated have been widely used. An insulating layer (cured article) is disposed between the conductor wiring layers of the multilayered wiring board. Such a multilayered wiring board may be produced by forming an insulating layer on a conductor wiring layer having conductive wires, disposing another conductor wiring layer having conductor wires on the insulating layer, and repeating these steps (laminating method). In many cases, the insulating layer of the multilayer wiring board is made from a radiation-sensitive insulation resin composition (hereinafter referred to from time to time as “resin composition”). If the insulating layer is made from a radiation-sensitive insulation resin composition, a pattern (through-hole, for example) for connecting the conductor wires can be formed using a lithographic technique.

As the radiation-sensitive insulation resin composition, a composition containing an epoxy resin, a photoacid generator, an inorganic filler, and a coupling agent (see Patent Document 1), a composition containing an alkali-soluble resin, a crosslinking agent, and a polymerization initiator (see Patent Document 2), a composition containing an alkali-soluble resin, a crosslinking agent, a polymerization initiator, and rubber particles (see Patent Document 3), and the like have been proposed.

### Patent Document 1: JP 2004-126159 A

### Patent Document 2: JP 11-60896 A

### Patent Document 3: JP 11-65116 A

### DISCLOSURE OF THE INVENTION

Although an insulating layer (cured article) made from the resin composition described in Patent Document 1 can be developed using an alkaline developer in photolithography, the insulating properties, adhesion to conductor wiring layers, and an effect of suppressing thermal deformation are not sufficient. An insulating layer (cured article) made from the resin composition described in Patent Document 2 or 3 can be developed using an alkaline developer in photolithography, has insulating properties and resolution properties, exhibits adhesion to conductor wiring layers, and suppresses thermal deformation (contraction), that is, has a small coefficient of linear expansion. However, these compositions do not necessarily exhibit sufficient adhesion and a sufficient effect of suppressing thermal deformation (contraction).

The present invention has been completed in view of the above-mentioned problems and has an objective of providing a radiation-sensitive insulation resin composition which can be developed using an alkaline developer in photolithography, does not incur damages in insulating properties and resolution properties, has an effect of suppressing thermal deformation well (i.e., has a sufficiently small coefficient of linear expansion), and can produce an insulating layer (cured article) exhibiting excellent adhesion to conductor wiring layers, a cured article made from the radiation-sensitive insulation resin composition, and an electronic device.

The inventors of the present invention have conducted extensive studies in order to achieve the above objective. As a result, the inventors have found that the above objective can be achieved by a radiation-sensitive insulation resin composition comprising (A) an alkali-soluble resin, (B) a crosslinking agent, (C) a radiation-sensitive acid generator, (D) an inorganic filler, and (E) crosslinked rubber particles. This finding has led to the completion of the present invention.

According to the present invention, the following radiation-sensitive insulation composition, cured article, and electronic device are provided.

[1] A radiation-sensitive insulation resin composition comprising (A) an alkali-soluble resin, (B) a crosslinking agent, (C) a radiation-sensitive acid generator, (D) an inorganic filler, and (E) crosslinked rubber particles.
[2] The radiation-sensitive insulation resin composition according to [1], wherein the inorganic filler (D) is inorganic particles having an average particle diameter of 1 to 500 nm.
[3] The radiation-sensitive insulation resin composition according to [1] or [2], wherein the content of the crosslinked rubber particles (E) is 1 to 40 mass % for 100 mass % of the total of the inorganic filler (D) and the crosslinked rubber particles (E).
[4] The radiation-sensitive insulation resin composition according to any one of [1] to [3], wherein the crosslinking agent (B) contains (i) a compound having at least two alkyl-etherized amino groups in the molecule.
[5] The radiation-sensitive insulation resin composition according to [4], wherein the compound (i) is an alkyl-etherized melamine.
[6] The radiation-sensitive insulation resin composition according to any one of [1] to [3], wherein the crosslinking agent (B) contains (ii) a compound containing an oxirane ring.
[7] The radiation-sensitive insulation resin composition according to [6], wherein the compound (ii) containing an oxirane ring is at least one member selected from the group consisting of a phenol novolac epoxy resin, a cresol novolac epoxy resin, and a bisphenol epoxy resin.
[8] A cured article produced by curing the radiation-sensitive insulation resin composition according to any one of [1] to [7].
[9] An electronic device comprising an insulating resin layer formed using the radiation-sensitive insulation resin composition according to any one of [1] to [7].

Since the radiation-sensitive insulation resin composition of the present invention comprises the alkali-soluble resin (A), the crosslinking agent (B), the radiation-sensitive acid generator (C), the inorganic filler (D), and the crosslinked rubber particles (E), the composition can be developed using an alkali developer in photolithography, does not incur damages in insulating properties and resolution properties, has an effect of suppressing thermal deformation well, and can produce an insulating layer exhibiting excellent adhesion to conductor wiring layers.

Since the cured product of the present invention is made from the radiation-sensitive insulation resin composition of the present invention, the article can be developed using an alkali in photolithography, does not incur damages in insulating properties and resolution properties, has an effect of suppressing thermal deformation well, and has excellent adhesion to conductor wiring layers.

Since the electronic device of the present invention can be developed using an alkali in a photolithographic process and is provided with an insulation resin layer made of a cured article which does not incur damages in insulating properties and resolution properties, has an effect of suppressing thermal deformation well, and has excellent adhesion to conductor wiring layers, the electronic device exhibits excellent dimensional stability when fabricated into a multilayer wiring board, and hardly produces distortion resulting from the difference of the coefficient of linear expansion between the semiconductor device and the insulation resin layer when mounted on a semiconductor chip. In addition, since the insulation resin layer has resistant to deformation with heat, the electronic device can be used continuously for a long period of time.

### BEST MODE FOR CARRYING OUT THE INVENTION

Preferred embodiments of the present invention are described below. Note that the present invention is not limited to the following embodiments. Various modifications and improvements may be made in the following embodiments within the scope of the present invention based on the knowledge of a person skilled in the art.

### [1] Radiation-Sensitive Insulation Resin Composition:

The radiation-sensitive insulation resin composition of the present invention comprises (A) an alkali-soluble resin, (B) a crosslinking agent, (C) a radiation-sensitive acid generator, (D) an inorganic filler, and (E) crosslinked rubber particles. Due to inclusion of these components, the composition can produce a cured article which can be developed by alkali, does not incur damages in insulating properties and resolution properties, has an effect of suppressing thermal deformation well, and can form an insulating layer (cured article) exhibiting excellent adhesion to conductor wiring layers. The radiation-sensitive composition of the embodiment will be described in detail.

### [1-1] (A) Alkali-Soluble Resin:

Although not specifically limited, particularly preferable alkali-soluble resins (A) contained in the radiation-sensitive insulation resin composition of the present invention include a resin having a phenolic hydroxyl group, a resin having a carboxyl group, a resin having an alcoholic hydroxyl group, a resin having a phenolic hydroxyl group and an alcoholic hydroxyl group, and a resin having a carboxyl group and an alcoholic hydroxyl group.

As examples of the alkali-soluble resin (A) having a phenolic hydroxyl group, a novolac resin, a copolymer of a polymerizable compound having a phenolic hydroxyl group and other monomers copolymerizable with the polymerizable compound having a phenolic hydroxyl group (hereinafter referred to from time to time as “other monomers (S-1)”), (such a copolymer may be hereinafter referred to from time to time as “copolymer (α)”), polyhydroxystyrene, a phenol-xylylene glycol condensed resin, a cresol-xylylene glycol condensed resin, and a phenol-dicyclopentadiene condensed resin can be given. Of these, the novolac resin is preferable.

As specific examples of the novolac resin that may be used, a phenol/formaldehyde condensed novolac resin, a cresol/formaldehyde condensed novolac resin, and a phenol naphtol/formaldehyde condensed novolac resin can be given. Such a novolac resin may be obtained by a generally known method such as a method of condensing a phenol and an aldehyde in the presence of a catalyst.

Examples of the phenols used to obtain the novolac resin include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, catechol, resorcinol, pyrogallol, α-naphthol, and β-naphthol.

Examples of the aldehydes used to obtain the novolac resin include formaldehyde, paraformaldehyde, acetaldehyde, and benzaldehyde.

The copolymer (α) may be obtained by copolymerizing the polymerizable compound having a phenolic hydroxyl group and (S-1) other monomers by a known method.

Examples of the polymerizable compound having a phenolic hydroxyl group used to obtain the copolymer (α) include hydroxystyrene and p-isopropenyphenol.

Examples of other monomers (S-1) used to obtain the copolymer (α) include alicyclic vinyl compounds having a hetero atom such as N-vinylpyrrolidone and N-vinylcaprolactam; vinyl compounds containing a cyano group such as acrylonitrile and methacrylonitrile; conjugated diolefins such as 1,3-butadiene and isoprene; vinyl compounds containing an amide group such as acrylamide and methacrylamide; (meth)acrylates such as methyl (meth)acrylate, ethyl (meth)acrylate, n-propyl (meth)acrylate, n-butyl (meth)acrylate, 2-hydroxyethyl (meth)acrylate, 2-hydroxypropyl (meth)acrylate, polyethylene glycol mono(meth)acrylate, polypropylene glycol mono(meth)acrylate, glycerol mono(meth)acrylate, phenyl (meth)acrylate, benzyl (meth)acrylate, cyclohexyl (meth)acrylate, isobornyl (meth)acrylate, and tricyclodecanyl (meth)acrylate; and aromatic vinyl compounds such as styrene, α-methylstyrene, p-methylstyrene, and p-methoxystyrene. These compounds may be used individually or in combination of two or more.

The copolymer (α) is preferably obtained by copolymerizing the polymerizable compound having a phenolic hydroxyl group and the aromatic vinyl compound and/or the conjugated diolefin. Specific examples include a copolymer obtained by copolymerizing hydroxystyrene and styrene and the like.

Polyhydroxystyrene may be obtained by polymerizing one or more aromatic vinyl compounds having a phenolic hydroxyl group such as o-hydroxystyrene, m-hydroxystyrene, p-hydroxystyrene, and p-isopropenylphenol by a known method.

The content of the structural units derived from the monomer having a phenolic hydroxyl group included in the alkali-soluble resin (A) having the phenolic hydroxyl group is preferably 50 to 100 mol %, more preferably 60 to 100 mol %, and particularly preferably 70 to 95 mol %. If the content is less than 50 mol %, the alkali solubility may be impaired. In the present specification, the term “content of structural units” refers to a value measured by NMR analysis. As an analyzer, “JEOL ECP500” manufactured by JEOL Ltd. may be used, for example.

The alkali-soluble resin (A) having a carboxyl group can be obtained by polymerizing a monomer having a carboxyl group and other monomers copolymerizable with the monomer having a carboxyl group (hereinafter referred to from time to time as “other monomers (S-2)”), for example.

As examples of the monomers having a carboxyl group, vinyl benzoate, o-carboxystyrene, and m-carboxystyrene can be given. Of these, vinyl benzoate is preferable due to its good polymerizability.

The content of the structural units derived from the monomer having a carboxyl group included in the alkali-soluble resin (A) having a carboxyl group is preferably 5 to 50 mol %, more preferably 10 to 40 mol %, and particularly preferably 10 to 30 mol %. If the content is less than 5 mol %, the alkali solubility may be impaired. If the content exceeds 50 mol %, the insulating properties may be impaired.

As other monomers (S-2), the same monomers given as examples of other monomers (S-1) for producing the copolymer (α) can be preferably used. Of these, aromatic vinyl compounds and acrylates are preferable due to their cosynthesizability.

The alkali-soluble resin (A) may be used in combination with a phenolic low-molecular-weight compound (hereinafter referred to from time to time as a “phenolic compound (a)”) in the radiation-sensitive insulation resin composition of the present invention. As specific examples of the phenolic compound (a), 4,4′-dihydroxydiphenylmethane, 4,4′-dihydroxydiphenyl ether, tris(4-hydroxyphenyl)methane, 1,1-bis(4-hydroxyphenyl)-1-phenylethane, tris(4-hydroxyphenyl)ethane, 1,3-bis[1-(4-hydroxyphenyl)-1-methylethyl]benzene, 1,4-bis[1-(4-hydroxyphenyl)-1-methylethyl]benzene, 4,6-bis[1-(4-hydroxyphenyl)-1-methyethyl]-1,3-dihydroxybenzene, 1,1-bis(4-hydroxyphenyl)-1-[4-{1-(4-hydroxyphenyl)-1-methylethyl}phenyl]ethane, and 1,1,2,2-tetra-(4-hydroxyphenyl)ethane can be given. The amount of the phenolic compound (a) in the resin composition is preferably in a range of 0 to 40 mass %, and particularly preferably in a range of 0 to 30 mass % for 100 mass % of the alkali-soluble resin (A).

Form the viewpoint of improving the resolution, thermal shock resistance, and heat resistance of the resulting insulating film, the weight average molecular weight of the alkali-soluble resin (A) is preferably 2000 or more, and more preferably 2000 to 50,000. If the weight average molecular weight is less than 2000, the radiation-sensitive insulation resin composition may have deficient thermal shock resistance and heat resistance. The weight average molecular weight in the present specification refers to a polystyrene-reduced weight average molecular weight measured by gel permeation chromatography (GPC).

The amount of the alkali-soluble resin (A) or the total amount of the alkali-soluble resin (A) and the phenolic compound (a), when the latter is used in combination, in the radiation-sensitive insulation resin composition of the present invention, in terms of a solid component concentration, is preferably 30 to 80 mass %, and more preferably 40 to 70 mass % for 100 mass % of the radiation-sensitive insulation resin composition. When the content of the alkali-soluble resin (A) is within the range of 30 to 80 mass %, the resin composition exhibits excellent resolution and insulating properties.

### [1-2] (B) Crosslinking Agent:

The crosslinking agent (B) contained in the radiation-sensitive insulation resin composition of the present invention has a function of a crosslinking component (curing component) reacting with the alkali-soluble resin (A). Although any component which has the above function may be used as the crosslinking agent (B) without a specific limitation, a component having (i) a compound having at least two alkyl-etherized amino groups in the molecule (hereinafter referred to from time to time as “(component (i))”), a component having (ii) a compound containing an oxirane ring (hereinafter referred to from time to time as “(component (ii))”), and a component containing the component (i) and the component (ii) are preferable.

The component (i) is a compound having at least two alkyl-etherized amino groups in the molecule. Examples of such a compound include nitrogen-containing compounds (compounds having an amino group) derived from (poly)methylolmelamine, (poly)methylolglycoluril, (poly)methylolbenzoguanamine, (poly)methylolurea, and the like having an active methylol group of which all or part of the methylol groups have been alkyl-etherified. As the alkyl group in the nitrogen-containing compound, a linear or branched alkyl group having 1 to 4 carbon atoms such as a methyl group, an ethyl group, and a butyl group is preferable. The alkyl groups in the nitrogen-containing compound may be either the same or different.

As specific examples of the component (i), alkyl-etherized melamines such as hexamethoxymethylmelamine and hexabutoxymethylmelamine, and alkyl-etherized urils such as tetramethoxymethyl glycoluril and tetrabutoxymethyl glycoluril can be given. Of these, alkyl-etherized melamines are preferable, with hexamethoxymethyl melamine being particularly preferable.

The component (i) may include oligomers produced by partial self-condensation of the above compounds. These components of the crosslinking agent (B) may be used either individually or in combination of two or more.

The component (i) is preferably used in an amount of 1 to 100 parts by mass, and more preferably 5 to 50 parts by mass for 100 parts by mass of the alkali-soluble resin (A). Impact resistance and chemical resistance can be obtained when the content of the component (i) is within the above range.

The component (ii) is not particularly limited inasmuch as the oxirane ring is contained in the molecule. Specific examples include epoxy resins having a phenolic hydroxyl group such as a phenol novolac epoxy resin, a cresol novolac epoxy resin, a bisphenol epoxy resin, a trisphenol epoxy resin, a tetraphenol epoxy resin, a phenol-xylylene epoxy resin, a naphtol-xylylene epoxy resin, a phenol-naphtol epoxy resin, and a phenol dicyclopentadiene epoxy resin; alicyclic epoxy resins and aliphatic epoxy resins. Of these, the phenol novolac epoxy resin, the cresol novolac epoxy resin, and the bisphenol epoxy resin are preferable due to durability (crack resistance) and insulation properties.

“EP-152” manufactured by Japan Epoxy Resins Co., Ltd. can be given as an example of commercially-available phenol novolac epoxy resins, “EOCN” series manufactured by Nippon Kayaku Co., Ltd. can be given as an example of commercially-available cresol novolac epoxy resins, and “NC3000” series manufactured by Nippon Kayaku Co., Ltd. can be given as an example of commercially-available bisphenol epoxy resins.

The amount of the component (ii) is preferably 1 to 70 parts by mass, and more preferably 3 to 30 parts by mass for 100 parts by mass of the alkali-soluble resin (A). If the amount is less than 1 part by mass, the chemical resistance of the insulating layer (cured article) formed from the composition may be decreased. If the amount is more than 70 parts by mass, the resolution of the insulating layer (cured article) may be decreased.

### [1-3] (C) Radiation-Sensitive Acid Generator:

The radiation-sensitive acid generator (C) (hereinafter referred to from time to time as “acid generator (C)”) contained in the radiation-sensitive insulation resin composition of the present invention is a compound which generates an acid by irradiation. The alkali-soluble resin (A) and the crosslinking agent (B) are reacted by the catalytic action of the acid generated by the acid generator (C) accompanied by dealcoholization and form alkali-insoluble components. After the formation of the alkali-insoluble components, the alkali-soluble resin (A) is dissolved in an alkaline developer and can be removed to form a negative-tone pattern.

The acid generator (C) is not particularly limited inasmuch as the compound generates an acid by irradiation. For example, an onium salt compound, a halogen-containing compound, a diazoketone compound, a sulfon compound, a sulfonic acid compound, a sulfonimide compound, a diazomethane compound, and the like can be given. Of these, the halogen-containing compound is preferable.

Examples of the onium salt compounds include iodonium salts, sulfonium salts, phosphonium salts, diazonium salts, and pyridinium salts. Preferable examples of the onium salt compounds are as follows. As the iodonium salts, diphenyliodonium trifluoromethansulfonate, diphenyliodonium p-toluenesulfonate, diphenyliodonium hexafluoroantimonate, diphenyliodonium hexafluorophosphate, and diphenyliodonium tetrafluoroborate can be given. As the sulfonium salts, triphenylsulfonium trifluoromethanesulfomate, triphenylsulfonium p-toluenesulfonate, triphenylsulfonium hexafluoroantimonate, 4-t-butylphenyldiphenylsulfonium trifluoromethanesulfonate, 4-t-butylphenyldiphenylsulfonium p-toluenesulfonate, and 4,7-di-n-butoxynaphtyltetrahydrothiophenium trifluoromethanesulfonate can be given.

Examples of the halogen-containing compounds include a haloalkyl group-containing hydrocarbon compound and a haloalkyl group-containing heterocyclic compound. Preferable examples of the halogen-containing compounds include 1,10-dibromo-n-decane, 1,1-bis(4-chlorophenyl)-2,2,2-trichloroethane, s-triazine derivatives such as phenyl-bis(trichloromethyl)-s-triazine, 4-methoxyphenyl-bis(trichloromethyl)-s-triazine, styryl-bis(trichloromethyl)-s-triazine, naphtyl-bis(trichloromethyl)-s-triazine, 2-[2-(furan-2-yl)ethenyl]-4,6-bis(trichloromethyl)-s-triazine, and 2-[2-(5-methylfuran-2-yl)ethenyl]-4,6-bis(trichloromethyl)-s-triazine. Among these, styryl-bis(trichloromethyl)-s-triazine, 4-methoxyphenyl-bis(trichloromethyl)-s-triazine, 2-[2-(furan-2-yl)ethenyl]-4,6-bis(trichloromethyl)-s-triazine, and 2-[2-(5-methylfuran-2-yl)ethenyl]-4,6-bis(trichloromethyl)-s-triazine are preferable.

Examples of the diazoketone compounds include a 1,3-diketo-2-diazo compound, a diazobenzoquinone compound, and a diazonaphtoquinone compound. A 1,2-naphtoquinonediazido-4-sulfonate compound of phenols can be given as a specific example.

As examples of the sulfone compounds, a β-ketosulfone compound, a β-sulfonylsulfone compound, an α-diazo compound of these compounds, and the like can be given. Specific examples include 4-trisphenacyl sulfone, mesitylphenacyl sulfone, and bis(phenacylsulfonyl)methane.

Examples of the sulfonic acid compounds include an alkylsulfonate, haloalkylsulfonate, arylsulfonate, and iminosulfonate. Preferable examples include benzoin tosylate, pyrogallol tristrifluoromethanesulfonate, o-nitrobenzyl trifluoromethanesulfonate, and o-nitrobenzyl p-toluenesulfonate.

Specific examples of the sulfonimide compounds include N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hept-5-ene-2,3-dicarboxyimide, and N-(trifluoromethylsulfonyloxy)naphtylimide.

Bis(trifluoromethylsulfonyl)diazomethane, bis(cyclohexylsulfonyl)diazomethane, bis(phenylsulfonyl)diazomethane, and the like can be given as specific examples of the diazomethane compounds. These acid generators (C) may be used individually or in combination of two or more.

The amount of the acid generator (C) is preferably 0.1 to 10 parts by mass, and more preferably 0.3 to 5 parts by mass for 100 parts by mass of the alkali-soluble resin (A). The amount of the acid generator (C) within the range of 0.1 to 10 parts by mass is preferable because the transparency to radiation is high, the resolution of the obtained pattern is high, and the heat resistance is sufficient.

### [1-4] (D) Inorganic Filler:

The inorganic filler (D) is added to the radiation-sensitive insulation resin composition of the present invention in order to control thermal expansion, reduce residual stress caused by the decreased shrinkage of the crosslinking agent (B), improve crack resistance, improve resistance to soldering heat, and the like. Specifically, the addition of the inorganic filler (D) makes it possible to prevent deformation of the materials around the cured article (e.g., silicon substrate and wiring) which can be caused by the expansion and shrinkage of the cured article due to a change in temperature, because the coefficient of linear expansion of the cured article formed from the radiation-sensitive insulation resin composition of the present invention becomes close to the coefficient of linear expansion of the materials around the cured article by the addition of the inorganic filler (D).

The inorganic filler (D) is not particularly limited inasmuch as the filler attains the above objectives. For example, inorganic oxides such as silicate, carbonate, clay, talc, and the like can be used. Among these, particles of the inorganic oxides are preferable. Among the inorganic oxides, silicate is preferable and crystalline silica is particularly preferable. The crystalline silica particles (hereinafter referred to from time to time as “crystalline silica”) have an advantage of exhibiting the best effect of the coupling agent because of the possession of the hydroxyl group on the surface. Moreover, since the refractive index of the crosslinking agent (B) and the refractive index of the crystalline silica are almost equal, light such as radiation is rarely reflected at the interface between the crosslinking agent (B) and the crystalline silica (inorganic filler (D)), and easily reaches the crosslinking agent (B) at the bottom of the cured article. In addition, it is possible to prevent the light reflected at the interface between the crosslinking agent (B) and the crystalline silica to travel below the mask. Examples of the particles of the crystalline silica include “MEK-ST” manufactured by Sin-Nakamura Chemical Co., Ltd. and “PL-2L” manufactured by Fuso Chemical Co., Ltd. Of these, “MEK-ST” manufactured by Sin-Nakamura Chemical Co., Ltd. is preferable.

The average particle diameter of the inorganic filler (D) is preferably 1 to 500 nm, more preferably 5 to 200 nm, and particularly preferably 10 to 100 nm. If the average particle diameter is within the range of 1 to 500 nm, excellent transparency to radiation and excellent resolution of the cured article formed from the composition can be achieved. In the present invention, the term “average particle diameter” refers to the average particle diameter measured by the light scattering method. The average particle diameter can be measured using “LPA-3000” manufactured by Otsuka Electronics Co., Ltd., for example.

The amount of the inorganic filler (D) may be appropriately selected according to the purpose of use. For example, if the filler is used as a solder resist, the amount of the filler is preferably 5 to 50 parts by mass, more preferably 5 to 45 parts by mass, still more preferably 7 to 45 parts by mass, particularly preferably 7 to 40 parts by mass, and most preferably 10 to 40 parts by mass for 100 parts by mass of the alkali-soluble resin (A). The amount of the inorganic filler (D) within the range of 5 to 50 parts by mass is preferable because the resolution of the cured article formed from the composition is not impaired and the effect of suppressing the thermal expansion is achieved. Either one inorganic filler (D) may be used alone or two or more types of inorganic filler (D) may be used in combination.

### [1-5] (E) Crosslinked Rubber Particles:

A cured article having excellent insulation and excellent adhesion to copper (conductor wiring layer) (i.e., having excellent copper plating peel strength) can be obtained by adding the crosslinked rubber particles (E) to the radiation-sensitive insulation resin composition of the present invention.

Some radiation-sensitive insulation resin compositions generally used may contain a liquid rubber in order to improve adhesion (see Patent Document 2). Such a liquid rubber generally has fluidity at room temperature. For example, acrylic rubber (ACM), acrylonitrile-butadiene rubber (NBR), acrylonitrile-acrylate-butadiene rubber (NBA), and the like are known. If the radiation-sensitive insulation resin composition contains such a liquid rubber, the radiation-sensitive insulation resin composition exhibits improved adhesion, but may have a decreased resolution.

The liquid rubber is compatible with other components such as a solvent and a resin in the resin composition. The molecular weight and the amount of the liquid rubber included in the resin composition are limited so as to ensure compatibility with other components. Therefore, it is preferable for the radiation-sensitive insulation resin composition of the present invention to not substantially contain a liquid rubber. The expression “not substantially contain” refers to a content of less than 0.1 mass % for 100 mass % of the total amount of the resin composition.

On the other hand, the crosslinked rubber particles (E) contained in the radiation-sensitive insulation resin composition of the present invention are crosslinked copolymers in the form of particles and are dispersed in the resin composition. The crosslinked rubber particles (E) have an advantage of being capable of easily dispersed in an alkaline developer. Therefore, the crosslinked rubber particles (E) are dispersed in the alkaline developer when the alkali-soluble resin (A) is dissolved in the alkaline developer, which leads to exhibition of excellent resolution. In other words, an excellent resolution can be achieved because the crosslinked rubber particles (E) can be dispersed in an alkaline developer with ease, and because the crosslinked rubber particles (E) is dispersed in the resin composition. Accordingly, a radiation-sensitive insulation resin composition exhibits an excellent resolution if the crosslinked rubber particles (E) are added, when compared with the composition obtained by adding the liquid rubber. In addition, the cured article formed from the radiation-sensitive insulation resin composition is easily roughened if the crosslinked rubber particles (E) are included. Specifically, the surface of the cured article becomes adequately rough because the crosslinked rubber particles (E) are disposed even on the cured surface (of the cured article). The adequately roughened surface of the cured article exhibits excellent adhesion to copper (conductor wiring layer).

Since the crosslinked rubber particles (E) are dispersed in the resin composition, an amount of them ensures that the cured film (cured article) obtained from the composition exhibits crack resistance, elongation, and insulation. Accordingly, the radiation-sensitive insulation resin composition of the present invention exhibits an excellent resolution, crack resistance, elongation, and insulation.

The glass transition temperature of the crosslinked rubber particles (E) is preferably 20° C. or less, more preferably 10° C. or less, and particularly preferably 0° C. or less. If the glass transition temperature is more than 20° C., the crack resistance may be impaired. The crosslinked rubber particles (E) have a higher glass transition than the liquid rubber.

The crosslinked rubber particles (E) preferably contain a structural unit derived from a crosslinkable monomer having two or more unsaturated polymerizable groups (hereinafter referred to from time to time as “crosslinkable monomer”). For example, the crosslinked rubber particles (E) are obtained by copolymerizing the crosslinkable monomer and monomers other than the crosslinkable monomer copolymerizable with the crosslinkable monomer (hereinafter referred to from time to time as “other monomers (S-3)”). These monomers may be copolymerized by a known method.

Examples of the unsaturated polymerizable group contained in the crosslinkable monomer include a vinyl group, a (fluoro)(meth)acryloxy group shown by CH₂═C(R)COO—, wherein R is a hydrogen atom, a fluorine atom, a methyl group, or a fluoromethyl group, an acrylamide group shown by CH₂═CHCONH—, a styryl group shown by CH₂═CHC₆H₄—, a vinyl cyanide group shown by CH₂═C(CN)—, and a 2-cyanoacryloxy group shown by CH₂═C(CN)COO—. The unsaturated polymerizable groups contained in the crosslinkable monomer may be the same or different.

Specific examples of the crosslinkable monomer include compounds having two or more unsaturated polymerizable groups such as divinylbenzene, diallyl phthalate, ethylene glycol di(meth)acrylate, propylene glycol di(meth)acrylate, trimethylolpropane tri(meth)acrylate, pentaerythritol tri(meth)acrylate, polyethylene glycol di(meth)acrylate, and polypropylene glycol di(meth)acrylate. Of these, divinylbenzene is preferable.

The amount of the crosslinkable monomers added when preparing the crosslinked rubber particles (E) is preferably 1 to 20 mass %, and more preferably 2 to 10 mass % for 100 mass % of the total amount of the monomers used for copolymerization. If the amount is less than 1 mass %, crack resistance may be impaired because the crosslinking is not sufficient.

Specific examples of other monomers (S-3) include diene compounds such as butadiene, isoprene, dimethyl butadiene, chloroprene, and 1,3-pentadiene; unsaturated nitrile compounds such as (meth)acrylonitrile, α-chloroacrylonitrile, α-chloromethylacrylonitrile, α-methoxyacrylonitrile, α-ethoxyacrylonitrile, crotonic acid nitrile, cinnamic acid nitrile, itaconic acid dinitrile, maleic acid dinitirile, and fumaric acid dinitirile; unsaturated amides such as (meth)acrylamide, N,N′-methylenebis(meth)acrylamide, N,N′-ethylenebis(meth)acrylamide, N,N′-hexamethylenebis(meth)acrylamide, N-hydroxymethyl(meth)acrylamide, N-(2-hydroxyethyl)(meth)acrylamide, N,N-bis(2-hydroxyethyl)(meth)acrylamide, crotonic acid amide, and cinnamic acid amide; (meth)acrylates such as methyl (meth)acrylate, ethyl (meth)acrylate, propyl (meth)acrylate, butyl (meth)acrylate, hexyl (meth)acrylate, lauryl (meth)acrylate, polyethylene glycol (meth)acrylate, and polypropylene glycol (meth)acrylate;

aromatic vinyl compounds such as styrene, α-methylstyrene, o-methoxystyrene, p-hydroxystyrene, and p-isopropenylphenol; epoxy group-containing unsaturated compounds such as epoxy (meth)acrylates obtained by reacting diglycidyl ether of bisphenol A, diglycidyl ether of glycol, or the like with (meth)acrylic acid, hydroxyalkyl (meth)acrylate, or the like, urethane (meth)acrylates obtained by reacting hydroxyalkyl (meth)acrylate with polyisocyanate, glycidyl (meth)acrylate, and (meth)allyl glycidyl ether; unsaturated acid compounds such as (meth)acrylic acid, itaconic acid, β-(meth)acryloxyethyl succinate, β-(meth)acryloxyethyl maleate, β-(meth)acryloxyethyl phthalate, and β-(meth)acryloxyethyl hexahydrophthalate; amino group-containing unsaturated compounds such as dimethylamino (meth)acrylate and diethylamino (meth)acrylate; amide group-containing unsaturated compounds such as (meth)acrylamide and dimethyl(meth)acrylamide; and hydroxy group-containing unsaturated compounds such as hydroxyethyl (meth)acrylate, hydroxypropyl (meth)acrylate, and hydroxybutyl (meth)acrylate. These monomers may be used individually or in combination of two or more.

Of these, the diene compound such as butadiene, isoprene, (meth)acrylonitrile, alkyl (meth)acrylate, styrene, p-hydroxystyrene, p-isopropenylphenol, glycidyl (meth)acrylate, (meth)acrylic acid, hydroxyalkyl (meth)acrylate, the unsaturated acid compound, the hydroxyl group-containing unsaturated compound, and the like may be preferably used.

It is more preferable to use a monomer containing at least one diene compound such as butadiene, at least one unsaturated acid compound, and at least one hydroxyl group-containing unsaturated compound. It is particularly preferable to use a monomer containing butadiene (diene compound), hydroxylbutyl (meth)acrylate (hydroxyl group-containing unsaturated compound), and (meth)acrylic acid (unsaturated acid compound).

If other monomers (S-3) contain the diene compound, the amount of the diene compound is preferably 20 to 80 mass %, and more preferably 30 to 70 mass % for 100 mass % of the total amount of the monomer used for copolymerization. When the diene compound is copolymerized in an amount within the above range, soft and rubbery fine particles can be obtained, which particularly leads to prevention of cracking when an insulating layer is formed. Thus, it is possible to obtain an insulating layer with excellent durability.

If other monomers (S-3) contain the hydroxyl group-containing unsaturated compound, the amount of the hydroxyl group-containing unsaturated compound is preferably 10 to 60 mass %, and more preferably 20 to 50 mass % for 100 mass % of the total amount of the monomer used for copolymerization. When the hydroxyl group-containing unsaturated compound is copolymerized in an amount within the above range, the compatibility of the crosslinked rubber particles (E) and the alkali-soluble resin (A) is improved, which leads to exhibition of excellent crack resistance and elongation. Thus, it is possible to obtain an insulating layer (cured article) with excellent heat resistance and impact resistance.

If other monomers (S-3) contain the unsaturated acid compound, the amount of the unsaturated acid compound is preferably 1 to 20 mass %, and more preferably 1 to 10 mass % for 100 mass % of the total amount of the monomer used for copolymerization. If the unsaturated acid compound is copolymerized in an amount within the above range, the crosslinked rubber particles (E) formed from the composition have an acid group, which enable the resin composition to produce an insulating layer (cured article) with excellent alkali-solubility and excellent resolution.

The amount of the structural units derived from the diene compounds is preferably 20 to 80 mass %, and more preferably 30 to 70 mass % for 100 mass % of the total amount of the structural units. If the amount is less than 20 mass %, the pliability is insufficient and the crack resistance may be impaired. On the other hand, if the amount is more than 80 mass %, the compatibility with other resin components contained in the radiation-sensitive insulation resin composition may be impaired.

The average particle diameter of the crosslinked rubber particles (E) is usually 30 to 500 nm, preferably 40 to 200 nm, and more preferably 50 to 120 nm. The method of controlling the average particle diameter of the crosslinked rubber particles (E) is not limited. When the crosslinked rubber particles (E) are synthesized by emulsion polymerization, the average particle diameter may be controlled by adjusting the number of micelles during the emulsion polymerization according to the amount of the emulsifier used.

The amount of the crosslinked rubber particles (E) is preferably 1 to 50 parts by mass, and more preferably 5 to 30 parts by mass for 100 parts by mass of the alkali-soluble resin (A). If the amount is within the range of 1 to 50 parts by mass, the formed cured film has excellent thermal shock resistance and high heat resistance, enabling the resin composition to form a pattern with high resolution and ensuring the components have excellent dispersibility and compatibility with the other components.

The amount of the crosslinked rubber particles (E) is preferably 1 to 40 mass %, more preferably 10 to 40 mass %, and particularly preferably 25 to 35 mass % for 100 mass % of the total amount of the inorganic filler (D) and the crosslinked rubber particles (E). If the amount is less than 1 mass %, the crack resistance is low and the adhesion to copper may be impaired. On the other hand, the resolution may be impaired if the amount is more than 40 mass %.

### [1-6] Solvent:

In addition to the components mentioned above, a solvent may be added to the resin composition in order to improve the handling capability of the resin composition and adjust the viscosity and storage stability of the resin composition. The type of solvent (hereinafter referred to from time to time as “organic solvent”) is not limited. Examples of the solvent include ethylene glycol monoalkyl ether acetates such as ethylene glycol monomethyl ether acetate and ethylene glycol monoethyl ether acetate; propylene glycol monoalkyl ethers such as propylene glycol monomethyl ether, propylene glycol monoethyl ether, propylene glycol monopropyl ether, and propylene glycol monobutyl ether; propylene glycol dialkyl ethers such as propylene glycol dimethyl ether, propylene glycol diethyl ether, propylene glycol dipropyl ether, and propylene glycol dibutyl ether; propylene glycol monoalkyl ether acetates such as propylene glycol monomethyl ether acetate, propylene glycol monoethyl ether acetate, propylene glycol monopropyl ether acetate, and propylene glycol monobutyl ether acetate;

cellosolves such as ethyl cellosolve and butyl cellosolve; carbitols such as butyl carbitol; lactic acid esters such as methyl lactate, ethyl lactate, n-propyl lactate, and isopropyl lactate; aliphatic carboxylic acid esters such as ethyl acetate, n-propyl acetate, isopropyl acetate, n-butyl acetate, isobutyl acetate, n-amyl acetate, isoamyl acetate, isopropyl propionate, n-butyl propionate, and isobutyl propionate; other esters such as methyl 3-methoxypropionate, ethyl 3-methoxypropionate, methyl 3-ethoxypropionate, ethyl 3-ethoxypropionate, methyl pyruvate, and ethyl pyruvate; aromatic hydrocarbons such as toluene and xylene; ketones such as 2-heptanone, 3-heptanone, 4-heptanone, and cyclohexanone; amides such as N-dimethylformamide, N-methylacetamide, N,N-dimethylacetamide, and N-methylpyrrolidone; and lactones such as γ-butyrolactone. These organic solvents may be used individually or in combination of two or more.

### [1-7] Other Components:

Other additives such as an adhesive adjuvant, a sensitizer, and a leveling agent may be added to the radiation-sensitive insulation resin composition of the present invention in addition to the alkali-soluble resin (A), the crosslinking agent (B), the radiation-sensitive acid generator (C), the inorganic filler (D), and the crosslinked rubber particles (E) as well as solvents as required.

### [2] Method of Preparing Radiation-Sensitive Insulation Resin Composition:

The radiation-sensitive insulation resin composition of the present invention may be prepared by a known method. For example, the alkali-soluble resin (A), the crosslinking agent (B), the radiation-sensitive acid generator (C), the inorganic filler (D), the crosslinked rubber particles (E), the solvent, and other additives may be dispersed and mixed using a disperser such as a dissolver, a homogenizer, a three roll mill, or the like.

### [3] Cured Article:

The cured article of the present invention may be formed by curing the radiation-sensitive insulation resin composition of the present invention mentioned above. Since the cured article is formed from the radiation-sensitive insulation resin composition of the present invention, development using an alkaline developer in photolithography is possible, thermal deformation is well-controlled without losing the insulating properties and the resolution properties, and excellent adhesion to a conductor wiring layer is achieved.

The cured article of the present invention is preferably used as an insulating layer formed by the following method, for example. Specifically, a thin film (cured article) is formed by applying the radiation-sensitive insulation resin composition of the present invention to a laminated board or a silicone wafer on which a conductor wiring layer is formed, and drying the film to evaporate the solvent and the like. The thin film is then exposed to radiation through a mask with a desired pattern. After exposure to radiation, the thin film is heated (hereinafter referred to from time to time as “PEB”) to promote the reaction of the alkali-soluble resin (A) and the crosslinking agent (B) contained in the thin film. The thin film is then developed using an alkaline developer, and the unexposed area is dissolved and removed to obtain a thin film with a desired mask pattern. The thin film is then heated to impart dielectric properties to obtain an insulating layer on which a resist with a desired pattern is formed. The thin film is preferably washed with water and then dried after development using an alkaline developer.

The radiation-sensitive insulation resin composition may be applied to the conductor wiring layer using a dipping method, a spraying method, a bar coating method, a roll coating method, a spin coating method, or the like. The thickness of the thin film may be appropriately selected according to the use of the film. The thickness of the thin film is preferably 1 to 100 μm, and more preferably 10 to 50 μm. The thickness of the thin film (film thickness) may be appropriately controlled by coating method as well as adjusting the solid concentration and viscosity of the resin composition.

As examples of the radiation used for exposure, ultraviolet rays from a low-pressure mercury lamp, a high-pressure mercury lamp, a metal halide lamp, a g-line stepper, and an i-line stepper, electron beams, laser beams, and the like can be given. The amount of radiation is appropriately selected according to the light source used and the film thickness. For example, when the film thickness is 10 to 50 μm, the amount of the ultraviolet rays irradiated from the high-pressure mercury lamp is approximately 1,000 to 20,000 J/m². The PEB process is carried out after exposure to promote the curing reaction of the alkali-soluble resin (A) and the crosslinking agent (B). The PEB conditions vary according to the amount of the resin compositions and the thickness of the film. The PEB process is carried out for about 1 to 60 minutes usually at 70 to 150° C., and preferably at 80 to 120° C.

Examples of the method of development using an alkaline developer include a shower development method, a spray development method, an immersion development method, and a paddle development method. Development is usually carried out for about 1 to 10 minutes at 20 to 40° C. As an example of the alkaline developer, an alkaline aqueous solution in which approximately 1 to 10 mass % of an alkaline compound such as sodium hydroxide, potassium hydroxide, aqueous ammonia, tetramethylammonium hydroxide, choline, or the like is dissolved can be given. An appropriate amount of a water-soluble organic solvent such as ethanol or methanol and a surfactant may also be added to the alkaline aqueous solution.

The conditions for the heat treatment used to impart dielectric properties are not particularly limited. Such conditions are selected according to the use of the cured article from a temperature range of 50 to 250° C. and duration between 30 minutes and 10 hours. The heat treatment may be carried out twice in order to sufficiently cure the film and prevent deformation of the obtained resist pattern. Specifically, the film may be heated at 50 to 120° C. for five minutes to two hours (first stage) and then heated at 80 to 250° C. for 10 minutes to 10 hours (second stage). The heat treatment may be carried out using heating equipment such as an oven or an infrared furnace.

### [4] Electronic Device:

The electronic device of the present invention has an insulating resin layer (cured article) formed using the radiation-sensitive insulation resin composition of the present invention. Specifically, the electronic device of the present invention has the cured article of the present invention disposed in a desired position. Due to the possession of an insulating resin layer made from the radiation-sensitive insulation resin composition of the present invention, such an electronic device has various advantages. For example, a multilayer wiring board fabricated using the insulating resin layer has excellent dimensional stability. When a semiconductor device (chip) is mounted, the electronic device hardly produces a distortion due to the difference in coefficient of linear expansion between the semiconductor device and the insulating resin layer. In addition, since the insulating resin layer is not deformed by heat, the device can be continuously used for a long period of time.

The method of disposing the cured article is not particularly limited. For example, a method of applying the radiation-sensitive insulation resin composition to a conductive wiring layer arranged in a desired position to obtain a coated layer and drying the coated layer can be given. Alternatively, a previously formed cured article may be disposed at a desired position in the electronic device. The previously described method of application may be used for applying the radiation-sensitive insulation resin composition to the conductive wiring layer.

### EXAMPLES

The present invention is described in detail below by way of examples. Note that the present invention is not limited to the following examples. “Part(s)” and “%” in Examples and Comparative Examples are expressed on a mass basis, unless other wise indicated. Methods of measuring various property values and methods of evaluating various characteristics are described below.

### [Resolution]

A plate made of a glass epoxy resin with a copper metal layer clad on one side was used as a test piece. The radiation-sensitive insulation resin composition was applied to one side of the plate using a spin coater (“1H-360S” manufactured by Mikasa Co., Ltd.). The coating was dried in a hot blast oven at 90° C. for 10 minutes to obtain a thin film with a thickness of about 20 μm after drying. The thin film was irradiated with an UV ray with a wavelength of 350 nm at a dose of 1000 to 2000 J/cm² from a high-pressure mercury lamp through a pattern mask using an aligner (“MA-100” manufactured by Karl Suss Co.). After heating in a hot blast oven at 90° C. for 10 minutes, the pattern was developed in a shower developing apparatus using a 1% sodium hydroxide aqueous solution for five minutes. The minimum dimension (μm) in the pattern on the thin film after development was taken as a value of developability evaluation.

### [Coefficient of Linear Expansion]

A lubricant layer was formed on one side of a polyethylene terephthalate film by applying a lubricant. The above described radiation-sensitive insulation resin composition was applied onto the parting layer using a spin coater (“1H-360S” manufactured by Mikasa Co., Ltd.) to form a thin film with a thickness of 50 μm. The entire surface of the thin film was irradiated at a dose of 1000 mJ/cm² and then, heated at 170° C. for two hours to cure the film. The cured thin film was peeled-off from the polyethylene terephthalate film and used as a test piece. The linear expansion in a temperature range of −50 to 150° C. was measured using a linear expansion coefficient analyzer (“SS6100” manufactured by Seiko Instrument, Inc.) to calculate the coefficient of linear expansion (ppm).

### [Copper Plating Peel Strength]

A plate made of a glass epoxy resin with a copper metal layer clad on one side was used as a test piece. The above described radiation-sensitive insulation resin composition was applied to the plate using a spin coater (“1H-360S” manufactured by Mikasa Co., Ltd.) to form a thin film with a thickness of 30 μm. Then, the entire surface of the thin film was irradiated at a dose of 1000 mJ/cm² and then, heated at 170° C. for two hours to cure the film. The cured film was used as a test piece. The test piece was dipped in an NMP at 50° C. for ten minutes and then in a potassium permanganate/sodium hydroxide aqueous solution at 65° C. for ten minutes to roughen the surface (insulating layer). The test piece of which the surface was roughened was neutralized by dipping in a dilute aqueous solution at room temperature for five minutes and washed sufficiently with water. The test piece of which the surface was roughened was dipped in a palladium chloride catalyst solution at room temperature for six minutes to cause a plating catalyst to be supported on the roughened surface of the test piece (insulating layer). The plating catalyst was activated by dipping the test piece in a catalyst activation solution at 50° C. for three minutes. After the catalyst activation, the test piece was washed with water and subjected to electroless copper plating at 75° C. for five minutes. Then, using a copper sulfate-sulfuric acid aqueous solution, the test piece which is subjected to electroless copper plating was subjected to electrolysis copper plating at a current density of 2 A/dm². A copper metal layer with a total thickness of about 30 μm was thus formed on the entire surface of the test piece (insulating layer). The resulting test piece was treated with heat at 150° C. for one hour. The surface of the test piece was cut at intervals of 1 cm to remove strips using a peeling tester (manufactured by Yamamoto Plating Tester Co., Ltd.) from the end face. The peel strength of the copper metal layer (copper plating peel strength (g/cm)) was measured and taken as an evaluation value of adhesion to the conductor wiring layer.

### [Insulation (Volume Resistivity)]

The above described radiation-sensitive insulation resin composition was applied to an SUS substrate using a spin coater (Type “1H-360S” manufactured by Mikasa Co., Ltd.) and then, heated on a hot plate at 110° C. for three minutes to obtain a thin film with a uniform thickness of about 10 μm. The thin film was irradiated with a UV ray with a wavelength of 350 nm at a dose of 1000 J/cm² from a high-pressure mercury lamp using an aligner (“MA-100” manufactured by Karl Suss Co.), then, heated on a hot plate at 110° C. for three minutes (PEB), and further heated in a convection oven at 170° C. for two hours. After that, the SUS substrate was processed by a pressure cooker tester (manufactured by Tabai Espec Corp.) at 121° C. and 100% RH under 2.1 atm for 168 hours. The insulating layer was peeled-off from the SUS substrate and used as a test piece. Electrodes were disposed on each side of the test piece to measure the volume resistivity (ohm-cm) using a resistivity tester (manufactured by TOYO Corp.). The measured value was regarded as the evaluation value of insulation.

### [Crack Resistance]

In order to evaluate the durability of the cured article (thin film) prepared from the radiation-sensitive insulation resin composition, a crack resistance test was carried out as follows. The radiation-sensitive insulation resin composition was applied to an SUS substrate using a spin coater (Type “1H-360S” manufactured by Mikasa Co., Ltd.), on a silicon wafer having copper wires and then, heated on a hot plate at 110° C. for three minutes to obtain a thin film with a uniform thickness of about 10 μm. The thin film was irradiated with a UV ray with a wavelength of 350 nm at a dose of 1000 J/cm² from a high-pressure mercury lamp using an aligner (“MA-100” manufactured by Karl Suss Co.), then, heated on a hot plate at 110° C. for three minutes (PEB), and further heated in a convection oven at 170° C. for two hours. After that, the substrate was processed for 100 cycles at a temperature range of −50° C. to 150° C. using a heat cycle tester (manufactured by Tabai Espec Corp.). Then the thin film on the SUS substrate was observed by the naked eye after the heat treatment. A thin film with no cracks found as a result of the above observation was evaluated to have “Good” crack resistance, and a thin film on which a crack was observed was evaluated to have “Bad” crack resistance.

### Synthesis Example 1

### Synthesis of Alkali-Soluble Resin (A)

A 3 1 three-neck separable flask equipped with a stirrer, a condenser, and a thermometer was charged with 840 g of mixed cresol (m-cresol/p-cresol=60/40 (mol ratio)), 600 g of a 37% formaldehyde aqueous solution, and 0.36 g of oxalic acid. The separable flask was dipped in an oil bath and the mixture was reacted at 100° C. for three hours while stirring. After that, the temperature of the oil bath was increased to heat the mixture to 180° C. and the pressure of the separable flask was reduced to remove water and unreacted cresol, formaldehyde, and oxalic acid, thereby obtaining a molten cresol novolac resin. The molten cresol novolac resin was cooled to room temperature and recovered. The weight average molecular weight (Mw) of the recovered cresol novolac resin was 8700. The cresol novolac resin obtained in this Synthesis Example is indicated as “A-1” in Table 1.

### Synthesis Example 2

### Synthesis of Alkali-Soluble Resin (A)

74 parts of styrene and 26 parts of vinyl benzoate were mixed and reacted at 80° C. to obtain a copolymer (styrene-vinyl benzoate copolymer) having a structural unit derived from styrene and a structural unit derived from vinyl benzoate (structural unit derived from styrene/structural unit derived from vinyl benzoate=80:20 at a molar ratio and a weight average molecular weight of 10,000). The copolymer obtained in this Synthesis Example is indicated as “A-2” in Table 1.

### Synthesis Example 3

### (E) Synthesis of Crosslinked Rubber Particles

60 parts of butadiene, 32 parts of hydroxybutyl methacrylate, 6 parts of methacrylic acid, and 2 parts of divinylbenzene were mixed and polymerized by emulsion polymerization to obtain a copolymer having structural units derived from butadiene, structural unit derived from hydroxybutyl methacrylate, structural unit derived from methacrylic acid, and structural unit derived from divinylbenzene (structural units derived from butadiene/structural unit derived from hydroxybutyl methacrylate/structural unit derived from methacrylic acid/structural unit derived from divinylbenzene=60:32:6:2 (%) at a molar ratio and an average particle diameter of 70 nm). The copolymer obtained in this Synthesis Example is indicated as “E-1” in Table 1.

### Synthesis Example 4

### Synthesis of Liquid Rubber

60 parts of butadiene, 35 parts of acrylonitrile, and 5 parts of methacrylic acid were mixed and polymerized by solution polymerization to obtain a copolymer (liquid rubber) having structural units derived from butadiene, structural units derived from acrylonitrile, and structural units derived from methacrylic acid (structural units derived from butadiene/structural units derived from acrylonitrile/structural units derived from methacrylic acid=60:35:5 (%) at a molar ratio and an average molecular weight of 6000). The copolymer obtained in this Synthesis Example is indicated as “F-1” in Table 1.

### Example 1

100 parts of cresol novolac resin obtained in Synthesis Example 1, 25 parts of hexamethoxymethylmelamine (“Cymel 300” manufactured by Mitsui Cytec Ltd.) as a crosslinking agent (B), 1 part of styryl-bis(trichloromethyl)-s-triazine as a photoacid generator (C) (indicated as “C-1” in Table 1), 100 parts of crystalline silica (“MEK-ST” manufactured by Sin-Nakamura Chemical Co., Ltd., average particle diameter: 10 nm), 50 parts of the copolymer obtained in Synthesis Example 3 as crosslinked rubber particles (E), and 250 parts of ethyl lactate (solvent) were mixed to obtain a radiation-sensitive insulation resin composition.

The resulting radiation-sensitive insulation resin composition was evaluated by the above-mentioned methods of evaluation. As a result of evaluation in this Example, the composition was found to have resolution (minimum dimension) of 50 μm, a coefficient of linear expansion of 40 ppm, copper plating peel strength of 600 g/cm, and an insulation (volume resistivity) of 1×10¹² ohm·cm. The crack resistance of the composition was “Good”.

### Examples 2 to 6 and Comparative Examples 1 to 3

Radiation-sensitive insulation resin compositions were prepared in the same manner as in Example 1, except for using the components shown in Table 1. The evaluation results of the resin compositions are shown in Table 2. In Table 2, “B-2” indicates a phenol novolac epoxy resin (“EP-152” manufactured by Japan Epoxy Resins Co., Ltd.).

TABLE 1

| | | Alkali-soluble resin | | | | | | Radiation-sensitive acid | |
|---|---|---|---|---|---|---|---|---|---|
| | | (A) | | Crosslinking agent (B) | | | | generator (C) | |
| | | | Amount | | Amount | | Amount | | Amount |
| | | Type | (Part) | Type | (Part) | Type | (Part) | Type | (Part) |
| Example | 1 | A-1 | 100 | B-1 | 25 | — | — | C-1 | 1 |
| | 2 | A-2 | 100 | B-1 | 25 | — | — | C-1 | 1 |
| | 3 | A-1 | 100 | B-1 | 25 | B-2 | 5 | C-1 | 1 |
| | 4 | A-1 | 100 | B-1 | 25 | — | — | C-1 | 1 |
| | 5 | A-1 | 100 | B-1 | 25 | — | — | C-1 | 1 |
| | 6 | A-1 | 100 | B-1 | 25 | — | — | C-1 | 1 |
| Comparative | 1 | A-1 | 100 | B-1 | 25 | — | — | C-1 | 1 |
| Example | 2 | A-1 | 100 | B-1 | 25 | — | — | C-1 | 1 |
| | 3 | A-1 | 100 | B-1 | 25 | — | — | — | — |
| | 4 | A-2 | 100 | B-1 | 25 | — | — | C-1 | 1 |

| | | | | Crosslinked rubber | | | | | |
|---|---|---|---|---|---|---|---|---|---|
| | | Inorganic filler (D) | | particles (E) | | Other | | Solvent | |
| | | | Amount | | Amount | | Amount | | Amount |
| | | Type | (Part) | Type | (Part) | Type | (Part) | Type | (Part) |
| Example | 1 | D-1 | 100 | E-1 | 50 | — | — | Ethyl lactate | 250 |
| | 2 | D-1 | 100 | E-1 | 50 | — | — | Ethyl lactate | 250 |
| | 3 | D-1 | 100 | E-1 | 50 | — | — | Ethyl lactate | 250 |
| | 4 | D-1 | 50 | E-1 | 50 | — | — | Ethyl lactate | 250 |
| | 5 | D-1 | 100 | E-1 | 25 | — | — | Ethyl lactate | 250 |
| | 6 | D-1 | 50 | E-1 | 25 | — | — | Ethyl lactate | 250 |
| Comparative | 1 | — | — | — | — | — | — | Ethyl lactate | 250 |
| Example | 2 | — | — | E-1 | 50 | — | — | Ethyl lactate | 250 |
| | 3 | — | — | E-1 | 50 | — | — | Ethyl lactate | 250 |
| | 4 | D-1 | 100 | — | — | F-1 | 50 | Ethyl lactate | 250 |

A-1: cresol/formaldehyde condensed novolac resin (weight average molecular weight: 8,700)
A-2: styrene-vinyl benzoate copolymer (weight average molecular weight: 10,000)
B-1: hexamethoxymethylmelamine (“Cymel 300” manufactured by Mitsui Cytec Ltd.)
B-2: phenol novolac epoxy resin (“EP-152” manufactured by Japan Epoxy Resins Co., Ltd.)
C-1: styryl bis(trichloromethyl)-s-triazine
D-1: crystalline silica (“MEK-ST” manufactured by Sin-Nakamura Chemical Co., Ltd., average particle diameter: 10 nm)
E-1: copolymer of butadiene, hydroxybutyl methacrylate, methacrylic acid, and divinylbenzene
F-1: liquid rubber (weight average molecular weight: 6,000)

TABLE 2

| | | Resolution | Coefficient of | Copper | | |
|---|---|---|---|---|---|---|
| | | (minimum | linear | plating peel | Volume | |
| | | dimension | expansion | strength | resistivity | Crack |
| | | (μm)) | (ppm) | (g/cm) | (Ω-cm) | resistance |
| Example | 1 | 50 | 40 | 600 | 1 × 10¹² | Good |
| | 2 | 50 | 40 | 600 | 1 × 10¹² | Good |
| | 3 | 50 | 40 | 600 | 1 × 10¹² | Good |
| | 4 | 40 | 60 | 600 | 1 × 10¹² | Good |
| | 5 | 50 | 40 | 300 | 1 × 10¹² | Good |
| | 6 | 30 | 60 | 300 | 1 × 10¹² | Good |
| Comparative | 1 | 20 | 80 | 150 | 1 × 10¹² | Bad |
| Example | 2 | 50 | 80 | — | 1 × 10¹² | Good |
| | 3 | — | 80 | — | 1 × 10¹² | Good |
| | 4 | 100 | 40 | 400 | 1 × 10¹² | Bad |

As shown in Table 2, it was possible to produce an insulating layer (cured article) which can be developed by alkali, does not incur damages in insulating properties and resolution properties, has an effect of suppressing thermal deformation well, and exhibits excellent adhesion to conductor wiring layers by using the radiation-sensitive insulation resin compositions obtained in Examples 1 to 6 as compared with the radiation-sensitive insulation resin compositions obtained in Comparative Examples 1 to 4.

### INDUSTRIAL APPLICABILITY

The radiation-sensitive insulation resin composition of the present invention can be developed by alkali, does not incur damages in insulating properties and resolution properties, has an effect of suppressing thermal deformation well, and can form an insulating layer (cured article) with excellent adhesion to conductor wiring layers. Due to possession of these characteristics, the radiation-sensitive insulation resin composition can be suitably used particularly as a surface protecting film, interlayer dielectric material, and the like. The radiation-sensitive insulation resin composition of the present invention can be used as a negative-tone resin composition for a surface protection film (overcoat film, passivation film, etc.), an interlayer dielectric film (passivation film, etc.), a planarized film, and the like of semiconductor devices. The cured article obtained from the radiation-sensitive insulation resin composition of the present invention can be used as a circuit board. The present invention further provides a cured particle exhibiting excellent resolution properties as a permanent film resist and having excellent characteristics such as adhesion, thermal shock properties, electric insulation properties, patterning performance, and elongation, a negative-tone radiation-sensitive insulation resin composition capable of producing such a cured product, a cured article formed from the radiation-sensitive insulation resin composition, and a circuit substrate (electronic device) provided with the cured article.

1-9. (canceled)

10. A radiation-sensitive insulation resin composition comprising (A) an alkali-soluble resin, (B) a crosslinking agent, (C) a radiation-sensitive acid generator, (D) an inorganic filler, and (E) crosslinked rubber particles, the inorganic filler (D) being inorganic particles having an average particle diameter of 1 to 500 nm.

11. The radiation-sensitive insulation resin composition according to claim 10, wherein the content of the crosslinked rubber particles (E) is 1 to 40 mass % for 100 mass % of the total of the inorganic filler (D) and the crosslinked rubber particles (E).

12. The radiation-sensitive insulation resin composition according to claim 10, wherein the crosslinking agent (B) contains (i) a compound having at least two alkyl-etherized amino groups in the molecule.

13. The radiation-sensitive insulation resin composition according to claim 12, wherein the compound (i) is an alkyl-etherized melamine.

14. The radiation-sensitive insulation resin composition according to claim 10, wherein the crosslinking agent (B) contains (ii) a compound containing an oxirane ring.

15. The radiation-sensitive insulation resin composition according to claim 14, wherein the compound (ii) containing an oxirane ring is at least one member selected from the group consisting of a phenol novolac epoxy resin, a cresol novolac epoxy resin, and a bisphenol epoxy resin.

16. A cured article produced by curing the radiation-sensitive insulation resin composition according to claim 10.

17. An electronic device comprising an insulating resin layer formed using the radiation-sensitive insulation resin composition according to claim 10.
